(19) United States
(12) Patent Application Publication
(10) Pub. No.: US 2026/0231712 A1
(43) Pub. Date: Aug. 6, 2026

(54) METHOD OF CLEANING SEMICONDUCTOR WAFER, METHOD OF PRODUCING SEMICONDUCTOR WAFER, AND SEMICONDUCTOR WAFER

(71) Applicant: SUMCO Corporation, Tokyo (JP)

(72) Inventor: Ryoichi YANAI, Tokyo (JP)

(73) Assignee: SUMCO Corporation, Tokyo (JP)

(21) Appl. No.: 19/152,207

(22) PCT Filed: Dec. 14, 2023
(86) PCT No.: PCT/JP2023/044918

§ 371 Date: Jul. 30, 2025

(30) Foreign Application Priority Data
Feb. 22, 2023 (JP) 2023-026673

(51) Int. Cl. H10P 70/00; H10P 72/00

(52) U.S. Cl. CPC H10P 70/15; H10P 70/56; H10P 72/0414

(57) ABSTRACT

Provided is a method of cleaning a semiconductor wafer that can suppress occurrence of ladle-shaped defects. The method of cleaning a semiconductor wafer includes a spin cleaning process of supplying a cleaning liquid to at least a front surface of the semiconductor wafer while rotating the semiconductor wafer. The spin cleaning process includes one or more sets of combinations of an ozonized water cleaning process in which the cleaning liquid is ozonized water, followed by a hydrofluoric acid cleaning process in which the cleaning liquid is hydrofluoric acid. The method further includes a pretreatment process, prior to the spin cleaning process, of supplying a conductive liquid selected from the group consisting of hydrofluoric acid, carbonated water, and carbonated ozonized water to only a back surface of the semiconductor wafer while rotating the semiconductor wafer.

### TECHNICAL FIELD

The present disclosure relates to methods of cleaning semiconductor wafers, methods of producing semiconductor wafers, and semiconductor wafers, and in particular to a method of cleaning a semiconductor wafer and a method of producing a semiconductor wafer that include a process of single-wafer spin cleaning of a surface of a semiconductor wafer.

### BACKGROUND

In production of semiconductor wafers such as silicon wafers, there is a cleaning process in which a cleaning liquid is supplied to surfaces (front and back surfaces) of a wafer while the wafer is being rotated to remove particles attached to the surfaces (hereinafter also referred to as “single-wafer spin cleaning”).

A representative example of such a single-wafer cleaning method that cleans semiconductor wafers one by one is the single-wafer spin cleaning with repetitive use of ozonized water and dilute HF (SCROD) method, in which spin cleaning with ozonized water and spin cleaning with hydrofluoric acid are repeatedly carried out, as described in Patent Literature (PTL) 1. According to this method, an oxide film is formed on the wafer surface by spin cleaning with ozonized water, followed by spin cleaning with hydrofluoric acid to remove particles and the like on the wafer surface along with the oxide film.

### CITATION LIST

### Patent Literature

PTL 1: JP 2015-220284 A

### SUMMARY

### Technical Problem

In single-wafer cleaning, ladle-shaped defects, with a central concavity and peripheral raised edges, were sometimes observed. Such ladle-shaped defects have a protrusion height of 5 nm to 20 nm and a concave portion depth of 5 nm to 20 nm. Due to such ladle-shaped defects, there was a problem with the number of light point defects (LPD) worsening.

In view of the above problem, it would be helpful to provide a method of cleaning a semiconductor wafer and a method of producing a semiconductor wafer that can suppress occurrence of ladle-shaped defects in cleaning of a semiconductor wafer in a production stage before device formation.

### Solution to Problem

As a result of extensive studies aimed at solving the above problem, the present inventors discovered that the ladle-shaped defects are caused by electrostatic breakdown occurring between the semiconductor wafer and the cleaning liquid. Further, the inventors discovered that in the process of cleaning a semiconductor wafer, by supplying a conductive liquid to the back surface of the semiconductor wafer prior to spin cleaning of the front surface, static electricity charged on the semiconductor wafer can be eliminated via the conductive liquid. The conductive liquid is a liquid that secures conductivity, specifically a liquid selected from the group consisting of hydrofluoric acid, carbonated water, and carbonated ozonized water. By eliminating static electricity from the semiconductor wafer as described above, the occurrence of ladle-shaped defects on the front surface of the semiconductor wafer can be suppressed.

Although electrostatic breakdown also occurs in semiconductor wafers after device formation, electrostatic breakdown is mainly due to cleaning water consisting of pure water being sprayed onto the semiconductor wafers in an electrified state, which is a different problem from that addressed by the present disclosure. Further, in the cleaning of semiconductor wafers at the time of semiconductor wafer production, as in the present disclosure, hydrofluoric acid, ozonized water, and the like are used for cleaning, which is a completely different process from the cleaning of semiconductor wafers after device formation in terms of chemicals used and applications.

Primary features of the present disclosure are as follows.
[1] A method of cleaning a semiconductor wafer, the method comprising:
a spin cleaning process of supplying a cleaning liquid to at least a front surface of the semiconductor wafer while rotating the semiconductor wafer,
the spin cleaning process including one or more sets of combinations of an ozonized water cleaning process in which the cleaning liquid is ozonized water, followed by a hydrofluoric acid cleaning process in which the cleaning liquid is hydrofluoric acid; and
a pretreatment process, prior to the spin cleaning process, of supplying a conductive liquid selected from the group consisting of hydrofluoric acid, carbonated water, and carbonated ozonized water to only a back surface of the semiconductor wafer while rotating the semiconductor wafer.
[2] The method of cleaning a semiconductor wafer according to [1], wherein the conductive liquid is hydrofluoric acid.
[3] The method of cleaning a semiconductor wafer according to [1], wherein the conductive liquid is carbonated water.
[4] The method of cleaning a semiconductor wafer according to [1], wherein the conductive liquid is carbonated ozonized water.
[5] The method of cleaning a semiconductor wafer according to any one of [1] to [4], wherein a rotation speed of the semiconductor wafer in the pretreatment process is 10 rpm or more and 100 rpm or less.
[6] The method of cleaning a semiconductor wafer according to [5], wherein the spin cleaning process consists of a first period during which the rotation speed of the semiconductor wafer is the same as the rotation speed of the semiconductor wafer in the pretreatment process, followed by a second period during which the rotation speed of the semiconductor wafer is greater than 100 rpm and 1000 rpm or less.
[7] The method of cleaning a semiconductor wafer according to any one of [1] to [6], wherein a flow rate of the conductive liquid in the pretreatment process is 0.3 L/min or more and 1.5 L/min or less.
[8] The method of cleaning a semiconductor wafer according to any one of [1] to [7], wherein a supply time of the conductive liquid in the pretreatment process is 1.0 s or longer to 5.0 s or shorter.
[9] The method of cleaning a semiconductor wafer according to any one of [1] to [8], wherein the conductive liquid is ejected from a nozzle via a piping line and supplied to the back surface of the semiconductor wafer, and the piping line and the nozzle are made of non-metallic material.
[10] The method of cleaning a semiconductor wafer according to any one of [1] to [9], wherein the semiconductor wafer is a silicon wafer.
[11] A method of producing a semiconductor wafer, the method comprising the method of cleaning a semiconductor wafer according to any one of [1] to [10].
[12] A semiconductor wafer before device formation, wherein
a number of defects on a front surface of the semiconductor wafer is zero, when the defects are defined as each having a convex portion that has a height of 5 nm or more and 20 nm or less and a concave portion that has a depth of 5 nm or more and 20 nm or less adjacent to the convex portion.

### Advantageous Effect

According to the present disclosure, a method of cleaning a semiconductor wafer and a method of producing a semiconductor wafer are provided that can suppress occurrence of ladle-shaped defects.

### BRIEF DESCRIPTION OF THE DRAWINGS

In the accompanying drawings:

FIG. 1A is an SEM image observation result of a ladle-shaped defect; FIG. 1B is an AFM observation result of a ladle-shaped defect;

FIG. 2 is a flow diagram of a method of cleaning a semiconductor wafer according to an embodiment of the present disclosure;

FIG. 3A is a diagram illustrating a mechanism of electrostatic breakdown in a conventional method of cleaning; FIG. 3B is a diagram illustrating a mechanism of static elimination in a method of cleaning according to the present disclosure;

FIG. 4 is a cross-section view illustrating an arrangement of a semiconductor wafer and cleaning nozzles in a method of cleaning a semiconductor wafer according to an embodiment of the present disclosure;

FIG. 5A is a representative SEM image of a ladle-shaped defect in a tested example; FIG. 5B is a representative SEM image of a particle in a tested example; FIG. 5C is a representative SEM image of an SF defect in a tested example;

FIG. 6A is a graph illustrating total numbers of LPDs in tested examples; and FIG. 6B is a graph illustrating average numbers of LPD defect types in tested examples.

### DETAILED DESCRIPTION

The following describes an embodiment of a method of cleaning a semiconductor wafer according to the present disclosure. The embodiment described below is an example embodiment of the present disclosure, and does not limit configuration to the specific example described.

Hereinafter, a “front surface” of a semiconductor wafer is the surface on which a semiconductor device is fabricated or a different substrate is attached, and a “back surface” of the semiconductor wafer is a flat surface on the opposite side to the front surface. An identifier (laser mark) that records product information is engraved on the front surface or the back surface of the semiconductor wafer. Accordingly, the front surface and the back surface of the semiconductor wafer are clearly distinguished.

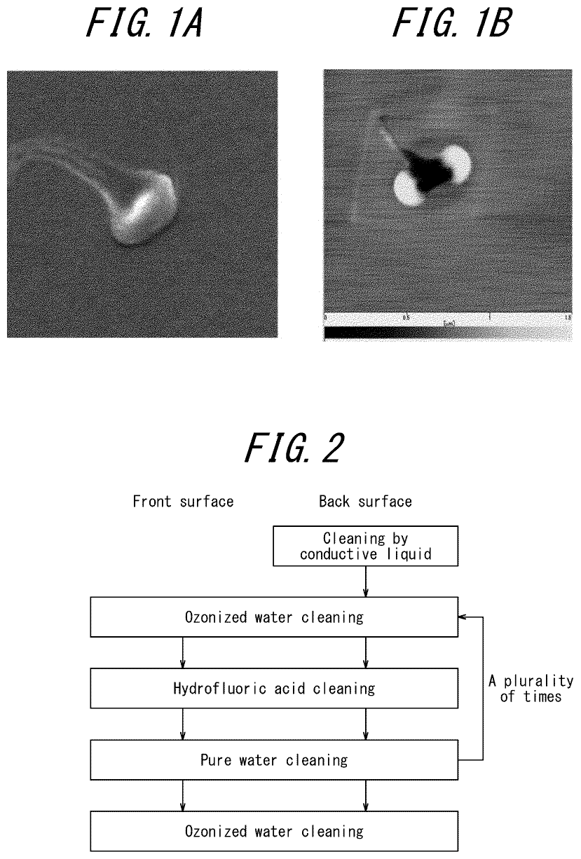

Hereinafter, a “ladle-shaped defect” is a defect that has a protrusion height of 5 nm to 20 nm and a concave portion depth of 5 nm to 20 nm. FIG. 1A illustrates an SEM image observation result of a ladle-shaped defect. FIG. 1B illustrates an AFM observation result of a ladle-shaped defect. A ladle-shaped defect has a central concavity and a raised periphery.

### [Method of Cleaning Semiconductor Wafer]

The method of cleaning a semiconductor wafer includes a spin cleaning process of supplying a cleaning liquid to at least a front surface of a semiconductor wafer while rotating the semiconductor wafer. Further, the spin cleaning process includes one or more sets of combinations of an ozonized water cleaning process in which the cleaning liquid is ozonized water, followed by a hydrofluoric acid cleaning process in which the cleaning liquid is hydrofluoric acid. Further, the method of cleaning a semiconductor wafer further includes a pretreatment process, prior to the spin cleaning process, of supplying a conductive liquid selected from the group consisting of hydrofluoric acid, carbonated water, and carbonated ozonized water to only a back surface of the semiconductor wafer while rotating the semiconductor wafer.

FIG. 2 illustrates a flow diagram of the method of cleaning a semiconductor wafer according to an embodiment of the present disclosure. In FIG. 2, the spin cleaning process includes an ozonized water cleaning process, a hydrofluoric acid cleaning process, and a pure water cleaning process, which are carried out a plurality of times in this order. Prior to the spin cleaning process, a pretreatment process is carried out to clean a back surface of the semiconductor wafer with a conductive liquid. The conductive liquid is a liquid selected from the group consisting of hydrofluoric acid, carbonated water, and carbonated ozonized water. Thus, the spin cleaning process may include, in addition to the ozonized water cleaning process and the hydrofluoric acid cleaning process, the pure water cleaning process in which the cleaning water is pure water. The pure water cleaning process in the spin cleaning process may be carried out after any process, and is preferably carried out after the hydrofluoric acid cleaning process. That is, the hydrofluoric acid cleaning process may be followed by the pure water cleaning process and then the ozonized water cleaning process, or the hydrofluoric acid cleaning process may be followed by the ozonized water cleaning process. Further, as illustrated in FIG. 2, it is preferable to carry out the ozonized water cleaning process, the hydrofluoric acid cleaning process, and the pure water cleaning process a plurality of times in this order, followed by the ozonized water cleaning process to complete the spin cleaning process. The spin cleaning process may be terminated after the pure water cleaning process.

In the spin cleaning process, an oxide film is formed on the semiconductor wafer surfaces in the ozonized water cleaning process, and particles and the like on the semiconductor wafer surfaces are removed along with the oxide film in the hydrofluoric acid cleaning process that follows the ozonized water cleaning process. The combination of the ozonized water cleaning process and the hydrofluoric acid cleaning process is one set, and one or more sets are carried out in the spin cleaning process. Preferably three or more sets of the combination of the ozonized water cleaning process and the hydrofluoric acid cleaning process are carried out in the spin cleaning process. More preferably, five or more sets are carried out. On the other hand, preferably seven or fewer sets of the combination are carried out in the spin washing process.

In the ozonized water cleaning process in the spin cleaning process, ozone concentration is not particularly limited as long as an oxide film is formed on the semiconductor wafer surface. The ozone concentration may be 15 mass ppm to 30 mass ppm. Further, a flow rate of the ozonized water is not particularly limited as long as an oxide film is formed on the semiconductor wafer surface. The flow rate may be 0.5 L/min to 1.5 L/min. Further, treatment time per ozonized water cleaning process is also not particularly limited as long as an oxide film is formed on the semiconductor wafer surface. The treatment time may be 10 s to 45 s.

In the hydrofluoric acid cleaning process in the spin cleaning process, hydrofluoric acid concentration may be set according to a wafer contamination level and is not particularly limited. The hydrofluoric acid concentration may be 0.50 mass % to 3.00 mass %. Further, a flow rate of the hydrofluoric acid may be set according to the wafer contamination level, and is not particularly limited. The flow rate may be 0.5 L/min to 1.5 L/min. Further, treatment time per hydrofluoric acid cleaning process may also be set according to the wafer contamination level and is not particularly limited. The treatment time may be 3 s to 20 s.

After the spin cleaning process is completed, the semiconductor wafer is preferably spin dried continuously without supplying the cleaning liquid, in order to remove the cleaning liquid from the semiconductor wafer surfaces and to dry the semiconductor wafer surfaces. The rotation speed of the semiconductor wafer in spin drying is not particularly limited. The rotation speed may be 1000 rpm to 1500 rpm.

According to the present disclosure, prior to the spin cleaning process, a pretreatment process is carried out of supplying a conductive liquid selected from the group consisting of hydrofluoric acid, carbonated water, and carbonated ozonized water to only the back surface of the semiconductor wafer while rotating the semiconductor wafer. The pretreatment process prior to the spin cleaning process eliminates static electricity from the semiconductor wafer and suppresses occurrence of ladle-shaped defects.

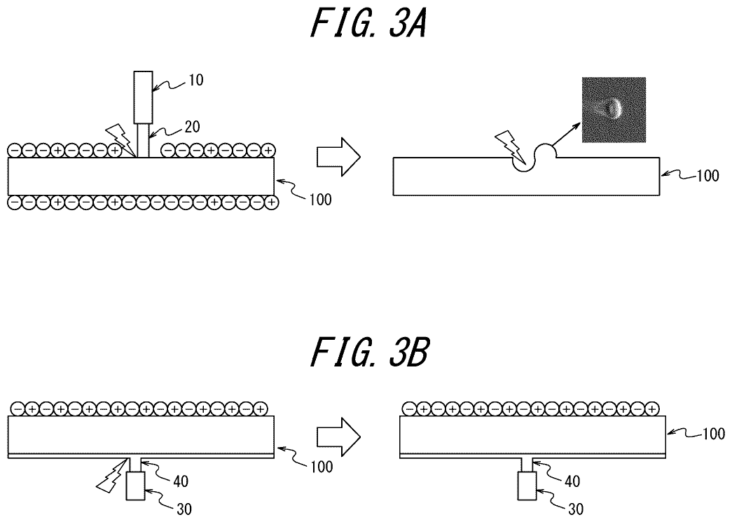

FIG. 3A illustrates a mechanism of electrostatic breakdown in a conventional method of cleaning. FIG. 3B illustrates a method of static elimination in the method of cleaning according to the present disclosure. In the production stage, semiconductor wafers are charged by transportation and the like. As illustrated in FIG. 3A, in a conventional method of cleaning, the cleaning liquid is supplied to the front surface of the semiconductor wafer before the back surface, and electrostatic breakdown occurs when a cleaning liquid 20 supplied from a front surface cleaning nozzle 10 comes into contact with a semiconductor wafer 100, forming a ladle-shaped defect on the front surface. In contrast, as illustrated in FIG. 3B, that is, according to the present disclosure, the pretreatment process is carried out prior to the spin cleaning process, and therefore a conductive liquid 40 supplied from a back surface cleaning nozzle 30 comes into contact with the back surface of the semiconductor wafer 100 first, thereby suppressing occurrence of ladle-shaped defects on the front surface. As a mechanism by which ladle-shaped defects do not occur on the front surface, it may be that the conductive liquid 40 supplied on the back surface acts as a ground to eliminate static electricity from the semiconductor wafer 100, or that electrostatic breakdown occurs when the conductive liquid 40 is supplied on the back surface and the semiconductor wafer 100 discharges. The back surface of the semiconductor wafer 100 is not required to be as smooth as the front surface, and there is no practical problem even when there is an uneven surface due to a ladle-shaped defect.

The conductive liquid supplied in the pretreatment process is a liquid selected from the group consisting of hydrofluoric acid, carbonated water, and carbonated ozonized water. Hereinafter, “carbonated ozonized water” refers to ozonized water containing carbonic acid. When the conductive liquid is hydrofluoric acid, the concentration of hydrofluoric acid is preferably 0.5 mass % to 3.0 mass %. Similarly, when the conductive liquid is carbonated water, the concentration of carbonic acid is preferably 5 mass ppm to 20 mass ppm. Similarly, when the conductive liquid is carbonated ozonized water, the concentration of carbonic acid is preferably 5 mass ppm to 20 mass ppm and the concentration of ozone is preferably 15 mass ppm to 30 mass ppm.

In the pretreatment process, static electricity of the semiconductor wafer may be suitably eliminated when the discharge liquid flow rate of the conductive liquid is 0.3 L/min or more. Accordingly, the discharge liquid flow rate of the conductive liquid is preferably 0.3 L/min or more. The discharge liquid flow rate is more preferably 0.8 L/min or more. On the other hand, when the discharge liquid flow rate of the conductive liquid is 1.5 L/min or less, a risk of liquid wrapping around or splashing back can be suitably reduced. Further, conductive liquid piping having a diameter of 4 mm is often used, and achieving a discharge liquid flow rate exceeding 1.5 L/min may be difficult due to apparatus structure. Accordingly, the discharge liquid flow rate of the conductive liquid is preferably 1.5 L/min or less.

In the pretreatment process, when a supply time of the conductive liquid is 1.0 s or longer, static electricity of the semiconductor wafer may be suitably eliminated. Accordingly, the supply time of the conductive liquid is preferably 1.0 s or longer. On the other hand, when the supply time of the conductive liquid is 5.0 s or shorter, liquid may be suitably prevented from completely spreading to the periphery of the back surface and LPD degradation due to liquid wrapping around to the front surface can be suitably suppressed. Accordingly, the supply time of the conductive liquid is preferably 5.0 s or shorter. The supply time is more preferably 3.0 s or shorter.

When the rotation speed of the semiconductor wafer in the pretreatment process is 10 rpm or more, the conductive liquid can be suitably supplied to the back surface of the semiconductor wafer. Accordingly, the rotation speed of the semiconductor wafer in the pretreatment process is preferably 10 rpm or more. The rotation speed is more preferably 30 rpm or more. On the other hand, by setting the rotation speed of the semiconductor wafer in the pretreatment process to a low value of 100 rpm or less, the conductive liquid may be suitably prevented from wrapping around to the front surface of the semiconductor wafer. Accordingly, the rotation speed of the semiconductor wafer in the pretreatment process is preferably 100 rpm or less. The rotation speed is more preferably 50 rpm or less.

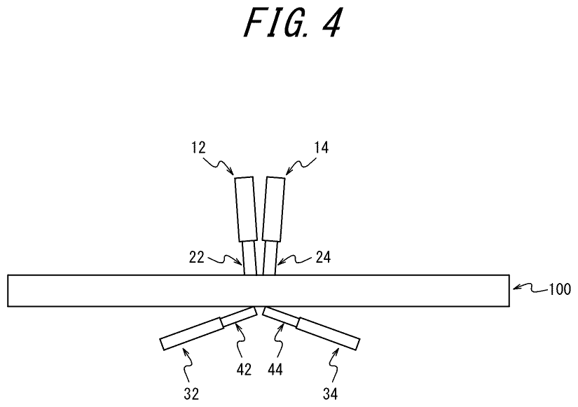

FIG. 4 illustrates a cross-section view of an arrangement of a semiconductor wafer and cleaning nozzles in the method of cleaning a semiconductor wafer according to an embodiment of the present disclosure. A front surface cleaning nozzle (for hydrofluoric acid) 12 supplies hydrofluoric acid 22 and a front surface cleaning nozzle (for ozonized water) 14 supplies ozonized water 24 to the front surface of the semiconductor wafer 100. A back surface cleaning nozzle (for hydrofluoric acid) 32 supplies hydrofluoric acid 42 and a back surface cleaning nozzle (for ozonized water) 34 supplies ozonized water 44 to the back surface of the semiconductor wafer 100. Each nozzle is arranged to supply the cleaning liquid and the like toward a center of the front surface or the back surface of the semiconductor wafer 100. Although not illustrated in FIG. 4, nozzles supplying pure water to the front and back surfaces of the semiconductor wafer 100 are also arranged at the same angles at different positions in the circumferential direction.

In FIG. 4, the front surface cleaning nozzle (for hydrofluoric acid) 12 and the front surface cleaning nozzle (for ozonized water) 14 are illustrated at 4° angles, and the back surface cleaning nozzle (for hydrofluoric acid) 32 and the back surface cleaning nozzle (for ozonized water) 34 are illustrated at 70° angles. Here, “nozzle angle” is the angle that a nozzle axis makes with a line perpendicular to the surface of the semiconductor wafer.

As illustrated in FIG. 4, the angle of nozzles at the front surface is typically smaller than the angle of nozzles at the back surface in cleaning of a semiconductor wafer. As a result, when the rotation speed of the semiconductor wafer is high when the cleaning liquid is supplied to the front and back surfaces, there is a risk that the cleaning liquid supplied to the back surface will reach the edge of the semiconductor wafer before the cleaning liquid supplied to the front surface, causing the cleaning liquid to wrap around to the front surface. Therefore, in a typical method of cleaning a semiconductor wafer, supply of cleaning liquid on the front surface is started some seconds earlier than on the back surface, and the supply of the cleaning liquid is adjusted, so that the cleaning liquid supplied to the front and back surfaces reaches the edge surface of the semiconductor wafer at the same time. According to the present disclosure, the conductive liquid is already supplied to the back surface of the semiconductor wafer during the pretreatment process, and therefore it is impossible to adjust the supply start time as described above. Therefore, according to the present disclosure the spin cleaning process preferably consists of a first period during which the rotation speed of the semiconductor wafer is the same as the rotation speed of the semiconductor wafer in the pretreatment process, followed by a second period during which the rotation speed of the semiconductor wafer is greater than 100 rpm and 1000 rpm or less. The presence of a first period at the start of the spin cleaning process when the rotation speed of the semiconductor wafer is the same as the rotation speed of the semiconductor wafer in the pretreatment process, that is, a period of low semiconductor wafer rotation speed, may suitably prevent the cleaning liquid supplied to the back surface from wrapping around to the front surface.

By setting the first period of the spin cleaning process to 1.0 s or longer, the time for the cleaning liquid on the front surface to reach the edge surface of the semiconductor wafer is suitably secured. Accordingly, the first period of the spin cleaning process is preferably 1.0 s or longer. The first period is more preferably 3.0 s or longer. On the other hand, from the viewpoint of liquid wrapping around to the front surface of the wafer, the first period of the spin cleaning process is preferably 5.0 s or shorter. After the cleaning liquid on the front surface reaches the edge surface of the semiconductor wafer, the semiconductor wafer may be spin cleaned normally by increasing the rotation speed of the semiconductor wafer. The rotation speed of the semiconductor wafer during the second period is preferably greater than 100 rpm and 1000 rpm or less. The second period may be 3.0 s or longer and 15.0 s or shorter.

The nozzle that supplies the cleaning liquid in the spin cleaning process may also supply the same type of conductive liquid as the cleaning liquid in the pretreatment process. When supplying carbonated water or carbonated ozonized water in the pretreatment process, carbonated water or carbonated ozonized water is supplied from the nozzle for pure water or the nozzle for ozonized water on the back surface. At this time, carbonated water is produced using a functional water apparatus, and carbonated ozonized water is produced by adding carbonic acid to ozonized water in an ozone production apparatus.

When the angle of the nozzle that supplies the cleaning liquid or the conductive liquid to the back surface of the semiconductor wafer is 60° or more, the impact of the cleaning liquid coming into contact with the back surface of the wafer can be suitably mitigated. Accordingly, the angle of the nozzle that supplies the cleaning liquid or the conductive liquid to the back surface is preferably 60° or more. On the other hand, when the angle of the nozzle that supplies the cleaning liquid or the conductive liquid to the back surface is 80° or less, the cleaning liquid can be suitably supplied to the back surface. Accordingly, the angle of the nozzle supplying the back surface with the cleaning liquid is preferably 80° or less.

On the other hand, when the angle of the nozzle that supplies the cleaning liquid to the front surface of the semiconductor wafer is 4° or more, the cleaning liquid may be suitably evenly supplied. Accordingly, the angle of the nozzle that supplies the cleaning liquid to the front surface is preferably 4° or more. On the other hand, when the angle of the nozzle that supplies the cleaning liquid to the front surface is 15° or less, a liquid film is suitably obtainable. Accordingly, the angle of the nozzle that supplies the cleaning liquid to the front surface is preferably 15° or less.

In the pretreatment process, when the nozzle that supplies the conductive liquid has an aperture diameter of 3.0 mm or more, a water column may be suitably formed by the supplied cleaning liquid, and static electricity may be suitably eliminated from the semiconductor wafer. Accordingly, the aperture diameter of the nozzle that supplies the conductive liquid is preferably 3.0 mm or more. The aperture diameter is more preferably 4.0 mm or more. On the other hand, when the nozzle that supplies the conductive liquid has the same diameter as the nozzle at the front surface, 6.0 mm or less, the risk of the liquid wrapping around to the front surface or splashing off a cup may be suitably reduced. Accordingly, the diameter of the nozzle that supplies the conductive liquid is preferably 6.0 mm or less.

In a case where the conductive liquid from the pretreatment process is discharged from a nozzle via a piping line and supplied to the back surface of the semiconductor wafer, the piping line and the nozzle are preferably non-metallic. The piping line and the nozzle may be made of non-metallic material to suitably avoid metal contamination. Further, the piping line and the nozzle are preferably made of resin such as perfluoroalkoxy alkane (PFA) or polytetrafluoroethylene (PTFE). Conventionally, methods for eliminating static electricity from cleaning water have included using metal piping lines or installing an earth in the piping. However, the cleaning liquid would come into contact with metal, and therefore there was concern that the cleaning liquid and the semiconductor wafer would be contaminated by metal. According to the present disclosure, the cleaning liquid is supplied as a water column by adjusting the nozzle diameter and the like, as described above, and the elimination of static electricity on the semiconductor wafer can be sufficient without the cleaning liquid coming into contact with metal, and therefore the piping line and the nozzle do not need to contain metal.

### [Method of Producing Semiconductor Wafer]

A method of producing a semiconductor wafer according to an embodiment of the present disclosure includes the method of cleaning a semiconductor wafer described above. This makes it possible to reliably produce semiconductor wafers for which the occurrence of ladle-shaped defects is suppressed. The method of producing a semiconductor wafer according to the present embodiment includes, for example:
a process of obtaining a single crystal ingot by the Czochralski method;
a process of slicing the single crystal ingot to obtain a plurality of semiconductor wafers;
a planarization process of lapping and grinding the semiconductor wafers;
a polishing process of double-sided polishing and subsequent single-sided finishing of the semiconductor wafers;
an epitaxial growth process of depositing an epitaxial layer on the semiconductor wafers;
a pre-cleaning process in which the semiconductor wafers are cleaned in a combination of SC1 cleaning tanks, HF tanks, ozone tanks, and the like, and then the semiconductor wafers are rinsed with pure water and subsequently dried;
a subsequent optional inspection process;
a method of cleaning the semiconductor wafers according to the present embodiment, including the pretreatment process and the spin cleaning process; and
a final inspection process including measuring the number of LPDs on the front surface of the semiconductor wafers.

The semiconductor wafers after production, that is, the semiconductor wafers that have passed the final inspection process, undergo device formation processing on the front surfaces thereof. That is, the present disclosure is applicable to semiconductor wafers before device formation.

### [Semiconductor Wafer]

The semiconductor wafer according to the present disclosure is preferably a silicon wafer. The semiconductor wafer is more preferably a single crystal silicon wafer. The semiconductor wafer is even more preferably a polished wafer or an epitaxial wafer.

By cleaning the semiconductor wafer using the method of cleaning described above, the semiconductor wafer for which occurrence of ladle-shaped defects is suppressed is obtainable. The semiconductor wafer before device formation according to the present disclosure has zero defects on the front surface of the semiconductor wafer, when the defects are defined as having a convex portion that has a height of 5 nm or more and 20 nm or less and a concave portion that has a depth of 5 nm or more and 20 nm or less. LPD defects other than ladle-shaped defects, such as particles (foreign matter) and stacking faults (SF), may be present.

### EXAMPLES

Silicon single crystal wafers (300 mm in diameter) after epitaxial growth treatment were prepared and placed in a single-wafer cleaning apparatus. The silicon single crystal wafers were subjected to static elimination for 2 s by a bar-type ionizer installed in a cleaning treatment tank. Cleaning was carried out on the silicon single crystal wafers after treatment by the ionizer. Table 1 lists cleaning conditions. For Example 1, the conductive liquid in Step 1 was hydrofluoric acid that had a concentration of 1.00 mass %, for Example 2, the conductive liquid in Step 1 was carbonated ozonized water that had a carbonic acid concentration of 15 mass ppm and an ozone concentration of 25 mass ppm, and for the comparative example, cleaning was carried out without Step 1. For both Examples 1 and 2 and the comparative example, Steps 1 and 2 were followed by Steps 3 through 5 repeated three times, then Steps 6 and 7, and this series of Steps 1 through 7 was repeated four times. Further, the nozzles supplying the cleaning liquid to the front surface of the silicon single crystal wafer each had a diameter of 6 mm and a nozzle angle of 4°. The nozzles supplying the cleaning liquid and the conductive liquid to the back surface of the semiconductor wafer each had a diameter of 4 mm and a nozzle angle of 70°.

TABLE 1

| | | | | Rotation | Flow | Treatment |
|---|---|---|---|---|---|---|
| | Front | Back | Concen- | speed | rate | time |
| Step | surface | surface | tration | (rpm) | (L/min) | (s) |
| 1 | — | HF or | HF: 1.00 | 30 | 1.0 | 3.0 |
| | | CO₂ | mass % or | | | |
| | | added | CO₂: 15 | | | |
| | | O₃ | mass ppm | | | |
| | | | O₃: 25 | | | |
| | | | mass ppm | | | |
| 2 | O₃ | O₃ | 25 mass | 30 | 1.0 | 3.0 |
| | | | ppm | | | |
| 3 | O₃ | O₃ | 25 mass | 300 | 1.0 | 15.0 |
| | | | ppm | | | |
| 4 | HF | HF | 1.00 mass | 300 | 1.0 | 4.0 |
| | | | % | | | |
| 5 | DIW | DIW | — | 300 | 1.0 | 2.0 |
| 6 | DIW | DIW | — | 300 | 1.0 | 15.0 |
| 7 (Dry) | — | — | — | 1500 | — | 25.0 |

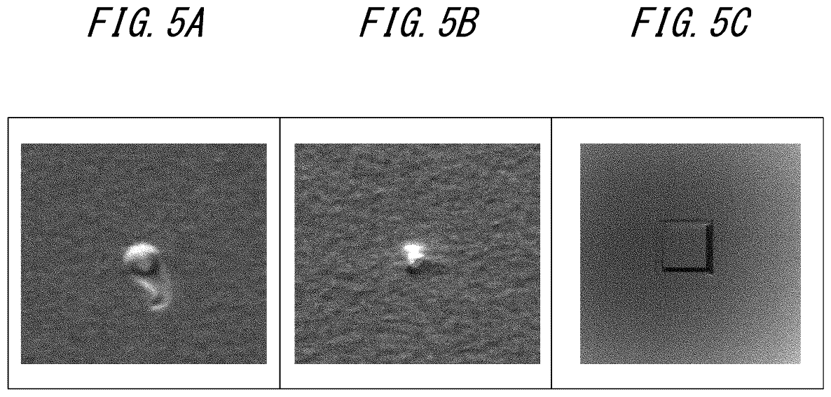

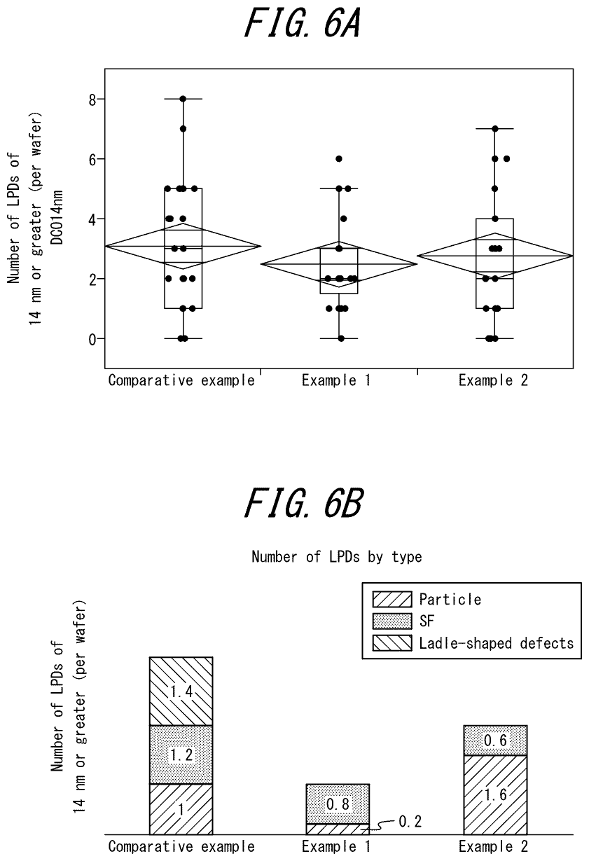

25 silicon single crystal wafers were prepared for each case after cleaning, and light point defects (LPD) of 14 nm or greater on the front surface of the silicon single crystal wafers were measured using Surfscan® (Surfscan is a registered trademark in Japan, other countries, or both) SP5 from KLA Corporation. Five sheets were randomly selected from each case, and for LPDs detected by SP5, defects were observed by scanning electron microscope (SEM) and classified into particle, SF defects, and ladle-shaped defects based on observation results. FIG. 5A illustrates a representative SEM image of a ladle-shaped defect in a tested example. FIG. 5B illustrates a representative SEM image of a particle in a tested example. FIG. 5C illustrates a representative SEM image of an SF defect in a tested example. Ladle-shaped defects were observed as defects that were accompanied by depressions and protrusions and had a tail fin-like shape. Particles were observed as spherical foreign bodies. SF defects were observed as defects that had linear or square edges. FIG. 6A is a graph illustrating the total number of LPDs. FIG. 6b is a graph illustrating the number of defect types among the LPDs. FIG. 6A plots the data for 25 wafers superimposed.

As illustrated in FIG. 6A, it is clear that the average number of LPDs detected was lower for Example 1 than for the comparative example, and also slightly lower in Example 2 than for the comparative example. As illustrated in FIG. 6B, ladle-shaped defects were observed in the comparative example, while no ladle-shaped defects were observed in Examples 1 and 2.

### INDUSTRIAL APPLICABILITY

According to the present disclosure, a method of cleaning a semiconductor wafer and a method of producing a semiconductor wafer are provided that can suppress occurrence of ladle-shaped defects.

### REFERENCE SIGNS LIST

100 semiconductor wafer
10 front surface cleaning nozzle
12 front surface cleaning nozzle (for hydrofluoric acid)
14 front surface cleaning nozzle (for ozonized water)
20 front surface cleaning liquid
22 front surface cleaning liquid (hydrofluoric acid)
24 front surface cleaning liquid (ozonized water)
30 back surface cleaning nozzle
32 back surface cleaning nozzle (for hydrofluoric acid)
34 back surface cleaning nozzle (for ozonized water)
40 conductive liquid
42 back surface cleaning liquid (hydrofluoric acid)
44 back surface cleaning liquid (ozonized water)

1. A method of cleaning a semiconductor wafer, the method comprising:
a spin cleaning process of supplying a cleaning liquid to at least a front surface of the semiconductor wafer while rotating the semiconductor wafer,
the spin cleaning process including one or more sets of combinations of an ozonized water cleaning process in which the cleaning liquid is ozonized water, followed by a hydrofluoric acid cleaning process in which the cleaning liquid is hydrofluoric acid; and
a pretreatment process, prior to the spin cleaning process, of supplying a conductive liquid selected from the group consisting of hydrofluoric acid, carbonated water, and carbonated ozonized water to only a back surface of the semiconductor wafer while rotating the semiconductor wafer.

2. The method of cleaning a semiconductor wafer according to claim 1, wherein the conductive liquid is hydrofluoric acid.

3. The method of cleaning a semiconductor wafer according to claim 1, wherein the conductive liquid is carbonated water.

4. The method of cleaning a semiconductor wafer according to claim 1, wherein the conductive liquid is carbonated ozonized water.

5. The method of cleaning a semiconductor wafer according to claim 1, wherein a rotation speed of the semiconductor wafer in the pretreatment process is 10 rpm or more and 100 rpm or less.

6. The method of cleaning a semiconductor wafer according to claim 5, wherein the spin cleaning process comprises a first period during which the rotation speed of the semiconductor wafer is the same as the rotation speed of the semiconductor wafer in the pretreatment process, followed by a second period during which the rotation speed of the semiconductor wafer is greater than 100 rpm and 1000 rpm or less.

7. The method of cleaning a semiconductor wafer according to claim 1, wherein a flow rate of the conductive liquid in the pretreatment process is 0.3 L/min or more and 1.5 L/min or less.

8. The method of cleaning a semiconductor wafer according to claim 1, wherein a supply time of the conductive liquid in the pretreatment process is 1.0 s or longer to 5.0 s or shorter.

9. The method of cleaning a semiconductor wafer according to claim 1, wherein the conductive liquid is ejected from a nozzle via a piping line and supplied to the back surface of the semiconductor wafer, and the piping line and the nozzle are made of non-metallic material.

10. The method of cleaning a semiconductor wafer according to claim 1, wherein the semiconductor wafer is a silicon wafer.

11. A method of producing a semiconductor wafer, the method comprising the method of cleaning a semiconductor wafer according to claim 1.

12. A semiconductor wafer before device formation, wherein
a number of defects on a front surface of the semiconductor wafer is zero, when the defects are defined as each having a convex portion that has a height of 5 nm or more and 20 nm or less and a concave portion that has a depth of 5 nm or more and 20 nm or less adjacent to the convex portion.
